(19) United States
(12) Patent Application Publication
(10) Pub. No.: US 2014/0084223 A1
(43) Pub. Date: Mar. 27, 2014

(54) CONDUCTIVE PASTE AND GLASS FRIT FOR SOLAR CELL ELECTRODES AND METHOD OF MANUFACTURING THEREOF

(71) Applicant: Ran Guo, Shenzhen (CN)

(72) Inventor: Ran Guo, Shenzhen (CN)

(21) Appl. No.: 13/730,939

(22) Filed: Dec. 29, 2012

(30) Foreign Application Priority Data
Sep. 25, 2012 (CN) 201210360864.5

(51) Int. Cl. H01L 31/0224

(52) U.S. Cl. CPC H01L 31/0224
USPC 252/514; 501/17

(57) ABSTRACT

The present invention pertains to solar cell technology. More specifically, the present invention relates to a conductive paste for solar cell light-receiving surface and a glass frit used for manufacture of the conductive paste. The glass frit comprises a glass network former, a glass network intermediate, a heavy metal fluxing agent, and functional agent. By controlling the ratio of the glass networking intermediate in the glass frit, the conductive paste can greatly reduce series resistance of the solar cell, and significantly increase the photovoltaic conversion efficiency. The solar cell using the present conductive paste can achieve consistently high open-circuit voltage, high short-circuit current, low series resistance, high filling factor, and high photovoltaic conversion efficiency.

### CROSS-REFERENCES TO RELATED APPLICATIONS

This application claims priority of China Patent Application. No. 201210360864.5, filed on Sep. 25, 2012, by Ran Guo, is commonly assigned and incorporated by reference herein to its entirety for all purposes.

### BACKGROUND OF THE INVENTION

The present invention relates to a solar cell, and, more particularly, to a conductive paste for solar cell light-receiving surface and a glass frit used for manufacture of the conductive paste.

Crystalline silicon solar cells are composed of a front side electrode, an anti-reflective coating, an emitter, a P-N junction, a base, an aluminum back surface field, and a back electrode. The front side electrode collects photon-generated charge carriers near the front side electrode and supplies current.

The front side electrode is formed by printing a conductive paste having a glass frit and silver powders on the anti-reflective coating surface of the crystalline silicon wafer as a certain pattern and then is sintered at a high temperature. In the sintering process, the glass frit is fused. The fused glass frit wets nearby silver powders and promotes sintering. During the process, a part of silver oxide is dissolved into the glass phases. With the temperature further rising, the glass phases sink and contact with the anti-reflective coating, which induces a redox reaction to etch and dissolve the anti-reflective coating. As a result, the contact between the conductive paste and the emitter is formed. During the redox reaction, silver crystal grains precipitate on the reaction interface. Afterwards, as temperature falls, silver colloid precipitates in the glass phase, thereby causing a formation of a conduction path from the electrode to the emitter—starting from the silver crystal grains through the glass layer containing silver colloid to the sintered silver bulk.

In the process of etching the anti-reflective coating via the redox reaction, if silver ionic mobility is low, reaction on interface is not sufficient. The incomplete etching leads to a higher resistance of the electrode path and affects the photovoltaic conversion efficiency of the crystalline silicon solar cell. By adopting a glass material with low softening point and low viscosity to take advantage of effective convection current, the concentration of silver ions can be maintained on the interface to ensure an effective reaction with the anti-reflective coating to obtain a good conductivity of the front electrode. However, if the temperature is too high, the glass material with low softening point and low viscosity may deposit too much between the silver bulk and the emitter, causing the glass layer with higher resistance and larger thickness. The glass material also may etch the anti-reflective coating and the emitter excessively, which not only increases series electrical resistance, but also easily causes shorting of circuit. If the temperature is too low, the glass material with low softening point and low viscosity cannot effectively etch the anti-reflective coating. Therefore, to form the front side electrode using conductive paste made by the glass material with low softening point and low viscosity, optimum sintering process parameters have to be limited only in a very narrow range of ±15° C. Presently, most of the conductive pastes on sale for manufacturing crystalline silicon solar front side electrode have these technical limitations.

### BRIEF SUMMARY OF THE INVENTION

The objective of the present invention is to provide a conductive paste to form a front side electrode on a solar cell light receiving surface. The solar cell using the present conductive paste according to the present invention can achieve high-quality open-circuit voltage, high short-circuit current, low series resistance, high filling factor, and high conversion efficiency formed in a sintering process with less restrictive processing parameters in sintering temperature and time, effectively enhancing the productivity. Embodiments of the present invention also provide a glass frit used for the manufacture of the conductive paste, which comprises a glass network former, a glass network intermediate, a heavy metal fluxing agent, and a functional agent.

The conductive paste according to an embodiment of the present invention comprises 70-90 wt % of a conductive powder, 0.1-10 wt % of a glass frit, and 5-25 wt % of an organic vehicle. The glass frit comprises 5-35 wt % of a glass network former, 5-30 wt % of a glass network intermediate, 50-89 wt % of a heavy metal fluxing agent, and 1-3 wt % of a functional agent.

The conductive paste used for the manufacture of front side electrodes on solar cell light receiving surface comprises a glass frit, which comprises a glass network former, a glass network intermediate, a heavy metal fluxing agent and a functional agent. By controlling the ratio of the glass network intermediate, the solar cell using the conductive paste can greatly reduce its series resistance, significantly increase the photovoltaic conversion efficiency, achieve high-quality open-circuit voltage, high short-circuit currents, and high filling factors. By controlling the ratio of the glass networking intermediate, the conductive paste used for the solar cell light receiving surface also is subjected to a broader range of sintering process conditions, thus enhancing the production capability.

### BRIEF DESCRIPTION OF THE DRAWINGS

Many aspects of the present invention can be better understood with reference to the following drawings. The components in the drawings are not necessarily drawn to scale, the emphasis instead being placed upon clearly illustrating the principles of the present apparatus. Moreover, in the drawings, like reference numerals designate corresponding parts throughout the several views.

FIG. 1 is a cross sectional view of the conductive paste on light receiving surface of a crystalline silicon solar cell after printing according to an embodiment of the present invention.

FIG. 2 is a cross sectional view of the conductive paste on light receiving surface of a crystalline silicon solar cell after sintering according to an embodiment of the present invention.

FIG. 3 shows open-circuit voltages of the crystalline silicon solar cells using the different conductive pastes according to embodiments 1-10 and comparatives 1-6 of the present invention.

FIG. 4 shows short circuit currents of the crystalline silicon solar cells using the different conductive pastes according to embodiments 1-10 and comparatives 1-6 of the present invention.

FIG. 5 shows series resistances of the crystalline silicon solar cells using different conductive pastes according to embodiments 1-10 and comparatives 1-6 of the present invention.

FIG. 6 shows filling factors of the crystalline silicon solar cells using different conductive pastes according to embodiments 1-10 and comparatives 1-6 of the present invention.

FIG. 7 shows photovoltaic conversion efficiency of the crystalline silicon solar cells using different conductive pastes according to embodiments 1-10 and comparatives 1-6 of the present invention.

### DETAILED DESCRIPTION OF THE INVENTION

The present invention relates to a conductive paste for solar cell light receiving surface and a glass frit used for manufacture of the conductive paste. Merely by way of examples, drawings, and embodiments, the present invention provides a method for manufacturing the conductive paste and the glass frit. The conductive paste comprises 70-90 wt % of a conductive powder, 0.5-10 wt % of a glass frit, and 5-25 wt % of an organic vehicle. Wherein each of 100 parts by weight of the glass frits comprises a glass network former in an amount of 5-35 parts by weight, a glass network intermediate in an amount of 5-30 parts by weight, a heavy metal fluxing agent in an amount of 50-89 parts by weight, and a functional agent in an amount of 1-3 parts by weight.

In a specific embodiment, the present invention provides a method to formulate a conductive paste used for solar cell light receiving surface. The conductive paste comprises a conductive powder, a glass frit having glass network intermediate, and an organic vehicle. In a specific embodiment, the conductive powder is silver powder. Based on one of the embodiments of the present invention, in 100 parts by weight of the conductive paste, the silver powder is in 70-90 parts by weight, the glass frit is in 0.5-10 parts by weight, preferably in 2-7 parts by weight, more preferably in 3-6 parts by weight, and the organic vehicle is in 5-25 parts by weight. If the silver powder is more than 90 parts by weight, the viscosity of the conductive paste is increased, causing difficulty of the printing of the conductive paste on solar cell light receiving surface. If the silver powder is less than 70 parts by weight, more voids among the silver bulk could be formed, which cause higher electrical resistance of the electrode path and poorer performance of the solar cell during the application. If the glass frit is more than 10 parts by weight, the conductive paste will have poor solder-ability and high resistance, which causes lower performance of the solar cell. If the glass frit is less than 0.5 parts by weight, the conductive paste could not effectively etch the anti-reflective coating layer during the sintering process, which causes poor contact or no contact between the silver bulk and the emitter of the solar cell. Moreover, the conductive paste with less than 0.5 wt % glass frits could not effectively promote the sintering of silver powder. If the organic vehicle is more than 25 parts by weight, more voids in the silver bulk could occurred, which cause higher electrical resistance of the electrode path and performance degradation of the solar cell. If the organic vehicle is less than 5 parts by weight, the viscosity of the conductive paste is greatly increased, which causes a difficulty printing of the conductive paste on solar cell light receiving surface.

In another specific embodiment, the present invention provides a particle size distribution of the conductive powders, which is in the range of 0.1 μm-10 μm. If the conductive powder is larger than 10 μm, it could block the printing screen. If the particle size of the conductive powder is less than 0.1 μm, the viscosity of the conductive paste is increased, which causes difficulty printing of the conductive paste on solar cell light receiving surface. Based on the embodiments of the present invention, the morphology of the conductive powder can be spherical, flake, aggregative state, colloid, etc., the morphologies of the conductive powders affect the sintering and printing of the conductive paste on solar cell surface, which further affect the performance of the solar cell in the application.

In yet another specific embodiment, the present invention provides the organic vehicle used for the manufacture of the conductive paste, which comprises an organic solvent, a binder, a wetting dispersant reagent, a thixotropic agent and other organic functional agents, etc.

Based on the embodiment of the present invention, the organic solvent can be a type of solvent with a medium or high boiling temperature such as alcohol (e.g., terpineol, butyl carbitol), alcohol ester (e.g., Alcohol ester-12), terpene and so on. The binder may be ethyl cellulose, polymethacrylate, alkyd resin, etc. The wetting dispersant reagent helps to disperse inorganic powders in the organic vehicle. The thixotropic agent is used to increase the thixotropy of the conductive paste in the printing process to ensure the resolution of electrode pattern and better aspect ratio. The thixotropic agent can be an organic thixotropic agent such as hydrogenated castor oil derivatives or polyamide wax, etc. Other organic functional agents may be added, such as microcrystalline wax may be added for reducing the surface tension, DBP is added for improving the flexibility of the paste, and PVB is added for improving the adhesion, and so on.

Based on the embodiment of the present invention, in 100 parts by weight of the organic vehicle, the organic solvent is 50-95 parts by weight, the binder is 1-40 parts by weight, the wetting dispersant reagent is 0.1-10 parts by weight, and both of the thixotropic agent and other organic functional agents are 1-20 parts by weight, respectively. The binder, the wetting dispersant reagent, and the thixotropic agent are terpineol, butyl carbitol, alcohol ester-12, ethyl cellulose, polymethacrylate, alkyd resin, hydrogenated castor oil derivatives or polyamide wax, etc. If the organic solvent is less than 50 parts by weight, viscosity of the conductive paste increases, which affect the printing performance. If the organic solvent is more than 95 parts by weight, it will lack of binder phases between paste powders, and result in the defects of the printing such as incomplete patterns, poor adhesion, and separation between the inorganic powders and the organic vehicle, etc. If the binder is less than 1 part by weight, it will lack of binding phases between powders, and result in that the printed pattern is not complete, the printed pattern performs a poor adhesion, and inorganic powders separates from the organic vehicle, etc. If the binder is more than 40 parts by weight, it will increase the viscosity of the paste and further affect the printing performance.

Based on the embodiment of the present invention, each of 100 parts by weight of the glass frit comprises a glass network former in an amount of 5-35 parts by weight, a glass network intermediate in an amount of 5-30 parts by weight, a heavy metal fluxing agent in an amount of 50-89 parts by weight, and a functional agent in an amount of 1-3 parts by weight.

The glass network former according to an embodiment of the present invention is one material selected from the group consisting of silicon (Si) oxide, Phosphorus (P) oxide, and germanium (Ge) oxide or a mixture of above materials. The glass network former is 5-35 parts by weight relating to 100 parts by weight of the glass frit. The heavy metal fluxing agent is lead (Pb) oxide or bismuth (Bi) oxide. The heavy metal fluxing agent is 50-89 parts by weight relating to 100 parts by weight of the glass frit. The glass network former and the heavy metal fluxing agent are melted together to form a homogeneous glass frit with a low melting point. Based on the embodiment of the resent invention, through controlling of the ratio between glass network former and heavy metal fluxing agent described above, the glass frit not only has a low melting point, but also prevents negative influence of both the glass network former and the heavy metal fluxing agent on the silver ion migration.

The glass network intermediate according to an embodiment of the present invention comprises a first component, a second component, and a third component. The first component may be one material selected from the group consisting of zinc oxide, cadmium oxide, magnesium oxide, beryllium oxide, indium oxide, and gallium oxide. The gallium oxide includes GaO and Ga₂O₃. The first component is 50-85 parts by weight relating to 100 parts by weight of the glass network intermediate, preferably 60-80 parts by weight. The second component may be one or both of the aluminum oxide and scandium oxide. The second component is 10-30 parts by weight relating to 100 parts by weight of the glass network intermediate, preferably 15-25 parts by weight. The third component may be one material selected from titanium oxide, zirconium oxide, hafnium oxide, yttrium oxide, and thorium oxide or their mixture. The third component is 1-25 parts by weight relating to 100 parts by weight of the glass network intermediate, preferably 5-18 parts by weight. It should be pointed out that the second component promotes viscosity of the glass network intermediate, and the third component promotes the crystallization tendency of the glass. Therefore, both the second component and the third component must be in an optimum range as described above. Based on the present invention, through the controlling of the ratio of the first component, the second component, and the third component described above, the viscosity and crystallization tendency of the glass frit could be remain in an optimum range so that the silver ionic mobility would not degrade. Through the controlling of the ratio of the first component, the second component, and the third component described above, the conductive paste per the present invention have favorable silver ionic mobility during the sintering process.

The glass frit used for the manufacture of the conductive paste further comprises 1-3 parts by weight of a functional agent. The functional agent may be one or more materials selected from a group consisting of alkali metals, alkaline-earth metals, and main subgroup elements. The functional agent can fill in glass network gaps in a cationic state or participate in the network structure, which can improve not only the performance of the glass frit but also the manufacturing process for forming the conductive paste. Alkali metal oxide, barium oxide, and boron oxide, etc. can be used to help to fuse. Tungsten oxide, oxidation alum, and molybdenum oxide, etc. can be used to reduce the surface tension. Calcium oxides increase hardening speed. Antimony trioxide, cerium oxide, and nitrate are used as oxidation clarifying agent. Manganese oxide can release oxygen in oxygen-poor conditions, thereby producing oxidizing atmosphere and promoting sufficient burning-out of the organic vehicle and dissolving silver into glass. The functional agent has 1-3 parts by weight relating to 100 parts by weight of the glass frit.

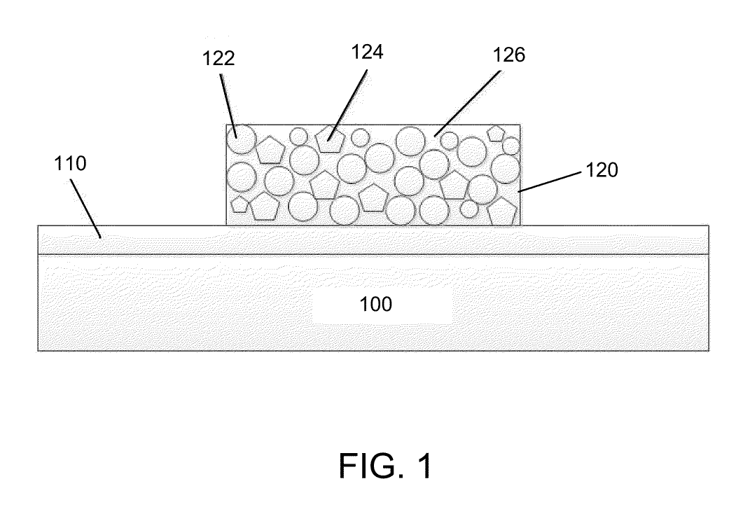

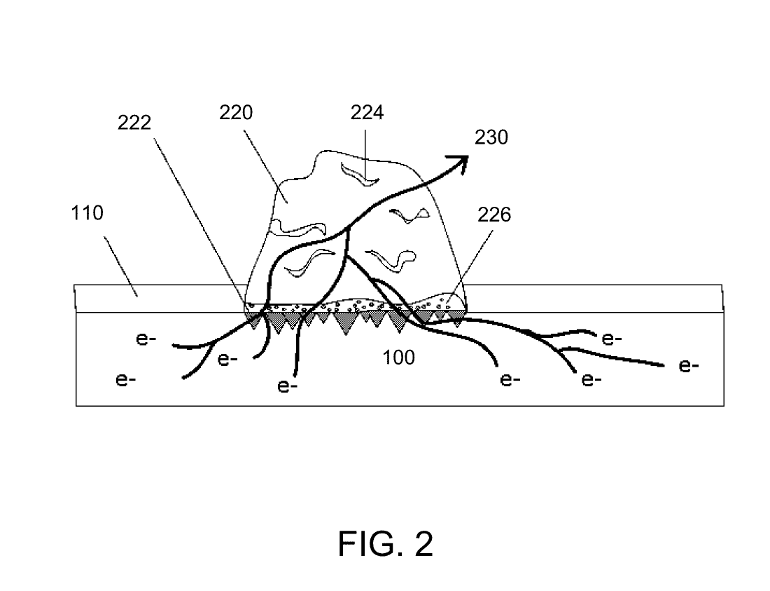

Referring now to FIG. 1, a cross sectional view of a partial conductive paste 120 on a light-receiving surface of a crystalline silicon solar cell after printing, wherein the conductive paste 120 comprises silver powders 122, glass frits 124, and organic media 126. The light-receiving surface includes an emitter 100 with an anti-reflection coating 110. The conductive paste 120 is then sintered at elevated temperatures (ramped from below 300° C. to above 700° C.) to form a silver bulk 220 as shown in FIG. 2. Through further processes, the silver bulk 220 is transformed into a front side electrode with conductive paths 230 formed therein to connect with the solar cell's light-receiving surface as shown in FIG. 2. During the sintering process, as the temperature rises above the glass softening temperature of about 450° C. the glass frits 124 (see FIG. 1) are first fused into glass phases 224 and wet nearby silver powders 122, promoting sintering of silver powders 122 into the silver bulk 220. Then a part of silver oxide within the silver bulk 220 is dissolved into the glass phases 224. As the sintering temperature further rises beyond the glass softening temperature range (over 620° C. up to 900° C.), the glass phases 224 become substantially liquid state and sink from most part of the paste 120 towards the interface between the paste and the anti-reflective coating 110. Once the materials from the glass frit are in contact with the anti-reflective coating 110, they start etching and dissolving partially the anti-reflective coating 110 via a redox reaction. The redox reaction results in a reactive interface between the silver bulk 220 and the emitter 100 of the solar cell. During the redox reaction, silver crystal grains 222 precipitate on the reactive interface. Near the end of the sintering process, temperature falls back to the softening temperature range (between 450° C. and 620° C.) before further cooling, a plurality of silver colloids 226 precipitates in the glass phases near the reactive interface, forming part of multiple conduction paths for the solar cell emitter surface. The conduction path connects via the silver crystal grains 222 through a glass layer containing silver colloids 226 to the sintered silver bulk 220. The electrical resistance between the silver bulk 220 and the solar cell emitter 100 contributes to the overall series resistance of the crystalline silicon solar cell, which has a great effect on photovoltaic conversion efficiency of the solar cell. The lower the electrical resistance between the silver bulk 220 and the emitter 100 of the solar cell is, the higher the photovoltaic conversion efficiency is. The present invention provides a conductive paste to form an electrode conduction path on solar cell surface, which has lower resistance between silver bulk and emitter of the solar cell and higher photovoltaic conversion efficiency.

The glass frit used for the manufacture of the conduct paste comprises a glass network former, a glass network intermediate, a heavy metal fluxing agent, and a functional agent. By controlling the ratio of the glass network former, the glass network intermediate, and the heavy metal fluxing agent, the conductive paste provides a great silver ionic mobility during the sintering process so that more silver ions react with the anti-reflective coating to form a uniform and dense film of silver crystal grains with a range of about 20 nm to about 150 nm. In addition, due to the promoted silver ionic mobility, the silver ions can be quickly and uniformly distributed in the fused glass fits, causing a uniform and dense silver colloid precipitation in the glass phases, reducing the resistance of the electrode conduction path and increasing the photovoltaic conversion efficiency of the crystalline silicon solar cell. At the same time, by controlling the precipitation of the silver, the crystalline silicon solar cell achieves high quality open-circuit voltage, high short-circuit current, low series resistance, high filling factor, and ultimately high photovoltaic conversion efficiency.

Further, the conductive paste of the present invention has a functionality to control the dissolving and precipitating of both the silver colloids and the silver crystal grains during the sintering process. This is achieved by controlling the ratio between glass network former, glass network intermediate, and fluxing agent as well as the ratio between the three components of glass network intermediate. As a result, uniform and dense silver colloids and silver crystal grains in a range of about 20 nm to about 150 nm are formed. Oversize or undersize effects of both of the silver colloids and the silver crystal grains are overcome. Controlling the size of the silver crystal grains during the sintering process is important. If the silver crystal grains are oversized, they might penetrate the emitter to the P-N junction, cause a short circuit and solar cell failure. Especially for crystalline silicon solar cells with shallow doped high sheet resistance (sheet resistance>75 Ω/sq.), its emitter is thinner and easily be broken. The conductive paste of the present invention has a functionality to control the silver crystal grain size in an optimum range of 20-150 nm during the sintering process. If the silver crystal grains are undersized or non-uniformly distributed, photon-generated charge carriers are consumed before arriving at the silver crystal grains, causing not only lower short-circuit current but also lower filling factor. If less silver colloids are produced during the sintering process, the resistance between the silver bulk and the emitters is high, which causes higher series resistance and lower filling factor of the solar cell. If the silver colloids precipitate too close to the reaction interface, the silver colloids cannot conduct the photon-generated charge carriers from the emitter to the silver bulk to obtain suitable series resistance and filling factor.

Based on an embodiment of the present invention, the glass frit used for the manufacture of the conductive paste comprises a glass network former in an amount of 5-35 parts by weight, a glass network intermediate in an amount of 5-30 parts by weight, a heavy metal fluxing agent in an amount of 50-89 parts by weight, and a functional agent in an amount of 1-3 parts by weight.

The glass network former based on the embodiment of the present invention is selected from the group consisting of silicon (Si) oxide, phosphorous (P) oxide, and germanium (Ge) oxide or their mixture. The glass network former is in 5-35 parts by weight relating to 100 parts by weight of the glass frit. The heavy metal fluxing agent is preferably lead (Pb) oxide or bismuth (Bi) oxide. The heavy metal fluxing agent is in 50-89 parts by weight relating to 100 parts by weight of the glass frit. The glass network former and the heavy metal fluxing agent are melted together to form a homogeneous glass frit which has a low melting point. Through the selection of the glass network former and the heavy metal fluxing agent with the ratio described above, the glass frit formed not only has a low melting point, but also prevent the negative influence of both the glass network former and the heavy metal fluxing agent on the silver ion migration during the sintering process.

The glass network intermediate based on the embodiment of the present invention comprises a first component, a second component, and a third component. The first component is selected from the group consisting of zinc oxide, cadmium oxide, magnesium oxide, beryllium oxide, In₂O₃ and gallium oxide or their mixture. The gallium oxide includes GaO and Ga₂O₃. The first component is in 50-85 parts by weight relating to 100 parts by weight of the glass network intermediate, preferably 60-80 parts by weight. The second component may be one or both of Al₂O₃ and scandium oxide. The second component is in 10-30 parts by weight relating to 100 parts by weight of the glass network intermediate, preferably 15-25 parts by weight. The third component is selected from the group consisting of titanium oxide, zirconium oxide, hafnium oxide, yttrium oxide or thorium oxide or their mixture. The third component is in 1-25 parts by weight relating to 100 parts by weight of the glass network intermediate, preferably 5-18 parts by weight. The second component promotes viscosity of the glass network intermediate. The third component promotes the crystallization tendency of the glass. However, increasing viscosity and the crystallization tendency of the glass frit could reduce the silver ionic mobility during the sintering. Therefore, through the selection of the first component, the second component, and the third component with the ratio described above, viscosity and crystallization tendency of the glass frit could be controlled in an optimum range and a great silver ionic mobility is achieved during the sintering. Through the selection of the first component, the second component, and the third component with above-mentioned parts by weight, the front side electrode conductive paste in the present invention has a favorable silver ionic mobility during the sintering process.

Further, the glass frit comprises 1-3 parts by weight of a functional agent. The functional agent includes one or more of alkali metals, alkaline-earth metals, and alkaline subgroup element. The functional agent can fill in glass network gaps in a cationic state or participate in the network structure, which could improve the performance of the glass frit, and further improve the performance of the conductive paste during the sintering process. Alkali metal oxide, barium oxide, and boron oxide, etc. can be used for accelerating the fusing of the glass frit during the sintering process. Tungsten oxide, vanadium pentoxide, and molybdenum oxide, etc. can be used for reducing the surface tension of the glass frit. Calcium oxides increase hardening speed. Antimony trioxide, cerium oxide, and nitrate are used as oxidation clarifying agent. Manganese oxide can release oxygen in oxygen-poor conditions, thereby producing oxidizing atmosphere and promoting sufficient burning-out of the organic vehicle and dissolving silver into glass. The functional agent has 1-3 parts by weight relating to 100 parts by weight of the glass frit.

The present invention provides a homogeneous glass frit with a softening temperature between 450° C. and 620° C., more preferably, the softening temperature is between 480° C. and 560° C. The glass frit is formed by controlling the ratio of the heavy metal fluxing agent and the glass network former. The conductive paste using the glass frit described above can be sintered with a conventional temperature profile. If the softening temperature of the glass frit is below 450° C., the glass frit may be prematurely softened and sunk during the sintering, which may block escape channels of the decomposed and vaporized organic components, causing poor density of the sintered silver bulk. Additionally, excessive glass frit may be congregated on the interface of the emitter, causing high resistance of the electrode conduction path. If the softening temperature of the glass frit is above 620° C., the glass frit may be softened slowly during the sintering, which cause the difficult of the wetting and dissolving of the silver powders. Moreover, the anti-reflective coating may not be effectively etched and removed. In order to keep the optimum softening temperature of the glass frit, the ratio between the heavy metal fluxing agent and the glass network former must be controlled as described above.

The glass frit according to the embodiment of the present invention can effectively improve the mobility of the silver ion fused state by the selection of the glass network intermediates with above-mentioned parts by weight. Thus, solar cells using the glass frits have good electrode path and excellent photovoltaic conversion efficiency.

### EMBODIMENTS

Many benefits can be achieved by applying the embodiments of the present invention. The present invention provides conductive pastes used for fabricating front side electrodes on light receiving surface of the crystalline silicon solar cells. Embodiments of the invention include making conductive pastes using the novel glass frits and applying the conductive pastes on crystalline silicon solar cells.

### Embodiments 1-10

The conductive pastes are prepared as listed in TABLE 1 as Embodiments 1-10, wherein the first step of each of the embodiments is to prepare glass frits with the compositions of silicon dioxide, the first component of the glass network intermediate, the second component of the glass network intermediate, the third component of the glass network intermediate, lead oxide and the functional agent as shown in TABLE 1. Then, the silver powder, organic vehicle, and glass frit are weighed to be proportions as shown in TABLE 1 for each of the embodiments, respectively, and then mixed using a stirring machine followed by dispersing using a three-roll mill. The conductive paste of each of the embodiments is then screen-printed on light receiving surface of the crystalline silicon solar cells followed by sintering to form front side electrodes. The sheet resistance of the crystalline silicon wafer used for the evaluation is 75 Ohm/sq. The dimensions of the wafer are 156 mm×156 mm. The conductive paste is printed with a pattern which has two bus bars with a width of 2000 μm and 78 fine fingers with a width of 90 μm. The screen used for the printing is 325 meshes, the thickness of the emulsion is 15 μm, the tension is 30 Newton, the scraper pressure is 0.3 Newton, the printing speed is 120 mm/s, and the clearance is 2.5 mm. In order to fully measure the performance of the crystalline silicon solar cells with the front side electrodes, back side electrodes are also prepared using Dupont PV505 of a back side silver paste and Rutech 8212 of a back side aluminum paste, which are printed on the back side surface of the crystalline silicon solar cells. Both the Dupont PV505 of a back side silver paste and Rutech 8212 of a back side aluminum paste are commercial available in the market. After printings, the crystalline silicon wafers are sintered in a Despatch infrared rapid sintering furnace (CDF-SL) with a belt speed of 240 inch-per-minute at a temperature of 900 Degrees Celsius, 930 Degrees Celsius, and 960 Degrees Celsius, respectively. For comparison, a commercial available conductive paste 33-462 from Ferro Company for light receiving surface of crystalline solar cell is also printed and sintered as same way as the Embodiments 1-10. It is shown in TABLE 1 as Reference 1.

TABLE 1

| | Silver Paste Components | | | | | | | |
|---|---|---|---|---|---|---|---|---|
| | | | Glass frit | | | | | |
| | | | | glass network intermediates | | | | Func- |
| | silver | Organic | Silicon | The first | The second | The third | Pb | tional |
| | powder | vehicle | dioxide | component | component | component | oxide | agent |
| No. | (wt %) | (wt %) | (wt %) | (wt %) | (wt %0 | (wt %) | (wt %) | (wt %) |
| Embodiment 1 | 90 | 9.5 | 0.025 | 0.045 | 0.0025 | 0.0025 | 0.419 | 0.006 |
| Embodiment 2 | 80 | 15 | 0.975 | 0.175 | 0.05 | 0.025 | 3.7 | 0.075 |
| Embodiment 3 | 70 | 20 | 1.85 | 1.5 | 0.9 | 0.6 | 5 | 0.15 |
| Embodiment 4 | 70 | 25 | 1.75 | 0.42 | 0.15 | 0.03 | 2.6 | 0.05 |
| Embodiment 5 | 75 | 18 | 1.96 | 0.42 | 0.105 | 0.175 | 4.2 | 0.14 |
| Embodiment 6 | 80 | 14 | 0.48 | 1.035 | 0.45 | 0.015 | 3.96 | 0.06 |
| Embodiment 7 | 85 | 5 | 2.5 | 0.704 | 0.132 | 0.044 | 6.5 | 0.12 |
| Embodiment 8 | 87 | 11 | 0.1 | 0.079 | 0.02 | 0.001 | 1.78 | 0.02 |
| Embodiment 9 | 70 | 25 | 1.75 | 0.48 | 0.108 | 0.012 | 2.5 | 0.15 |
| Embodiment 10 | 75 | 18 | 2.1 | 0.336 | 0.1232 | 0.1008 | 4.2 | 0.14 |
| Comparative 1 | 92 | 5 | 0.3 | 0.3825 | 0.045 | 0.0225 | 2.25 | 0 |
| Comparative 2 | 65 | 30 | 1.75 | 0.525 | 0.1875 | 0.0375 | 2.5 | 0 |
| Comparative 3 | 90 | 9.5 | 0.225 | 0.03 | 0.0075 | 0.0125 | 0.225 | 0 |
| Comparative 4 | 80 | 15 | 2.25 | 0.375 | 0.6 | 0.525 | 1.25 | 0 |
| Comparative 5 | 70 | 20 | 0.4 | 0.36 | 0.032 | 0.008 | 9.2 | 0 |

| | |
|---|---|
| Reference 1 | Commercial available silver paste 33-462 from Ferro Company |

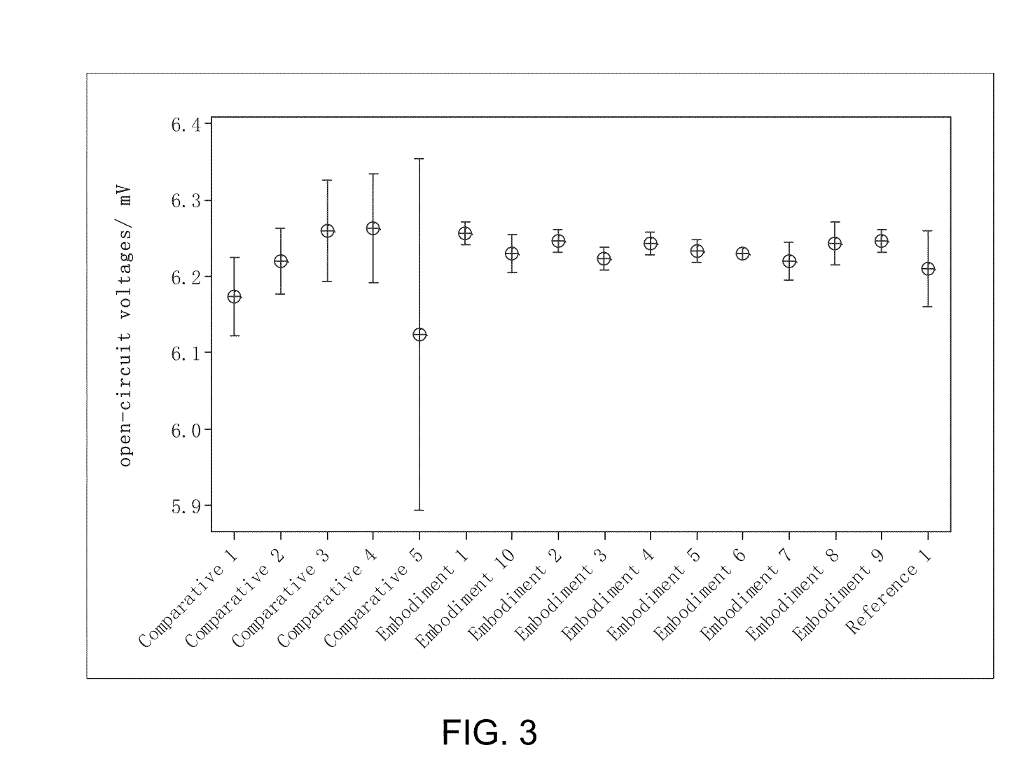

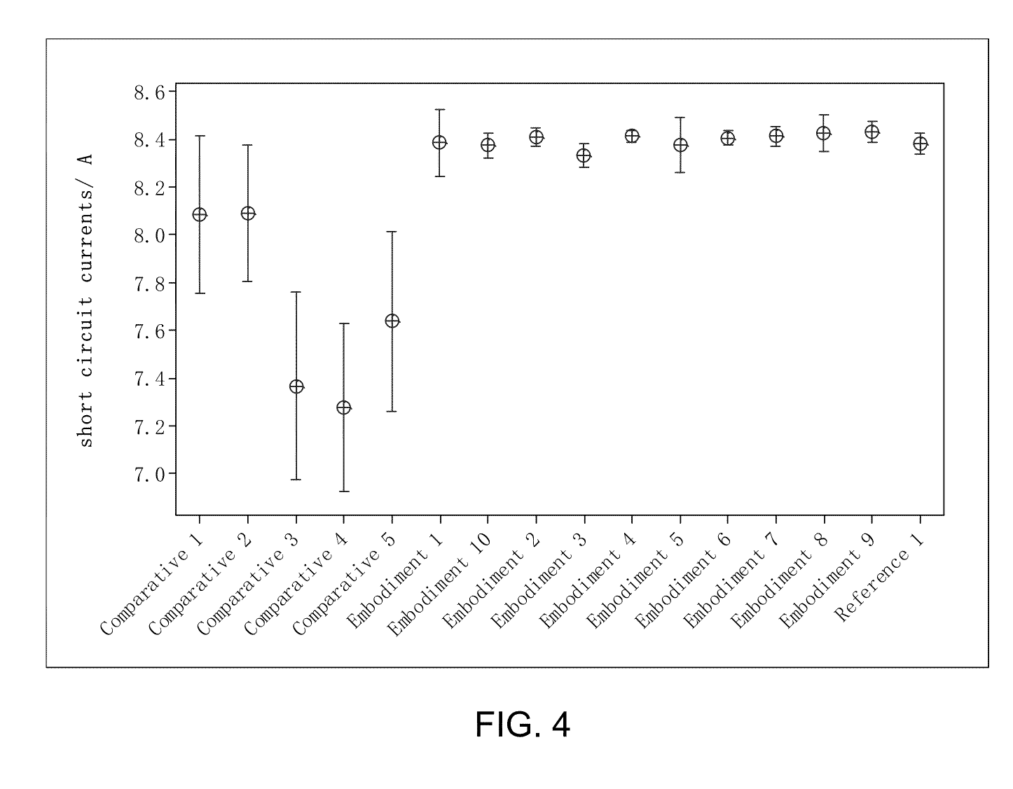

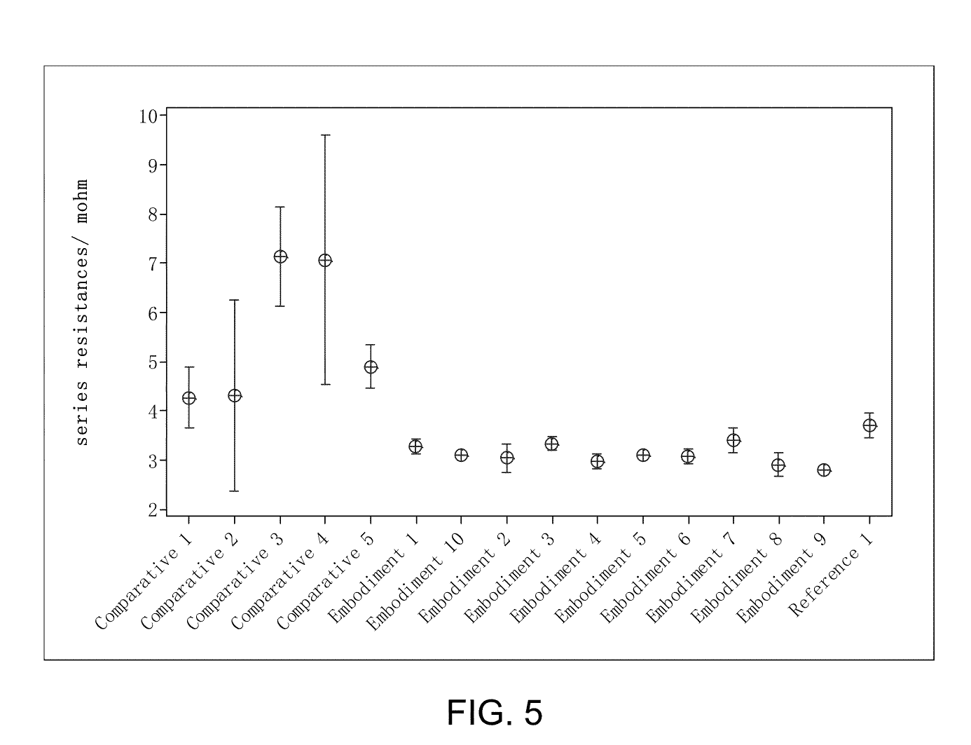

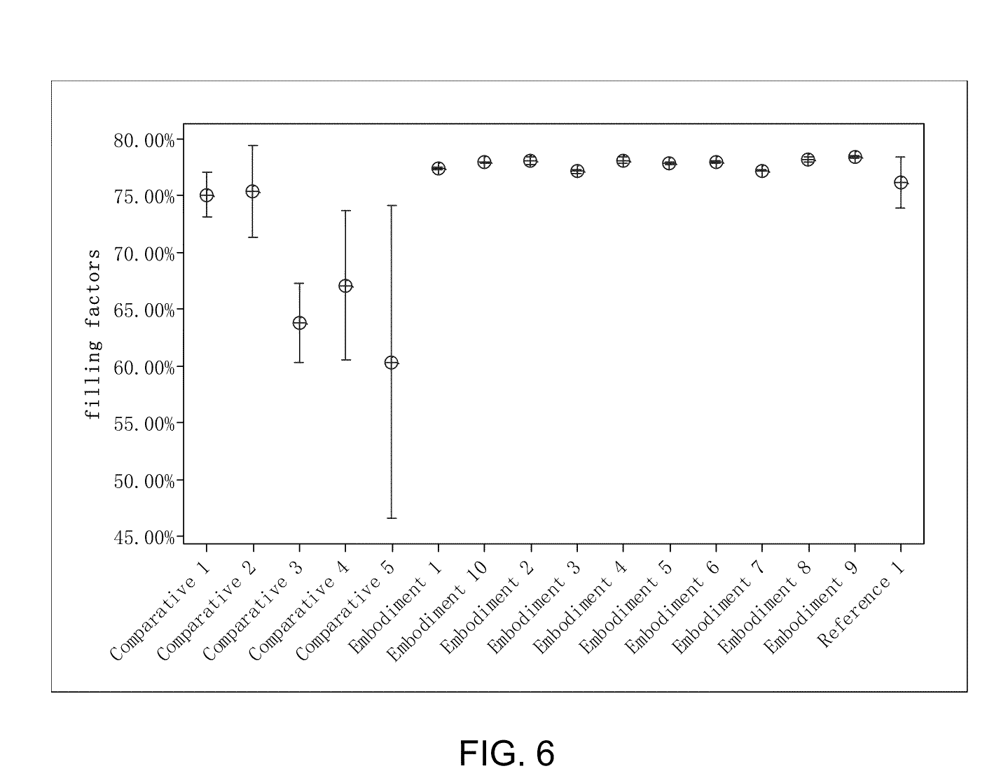

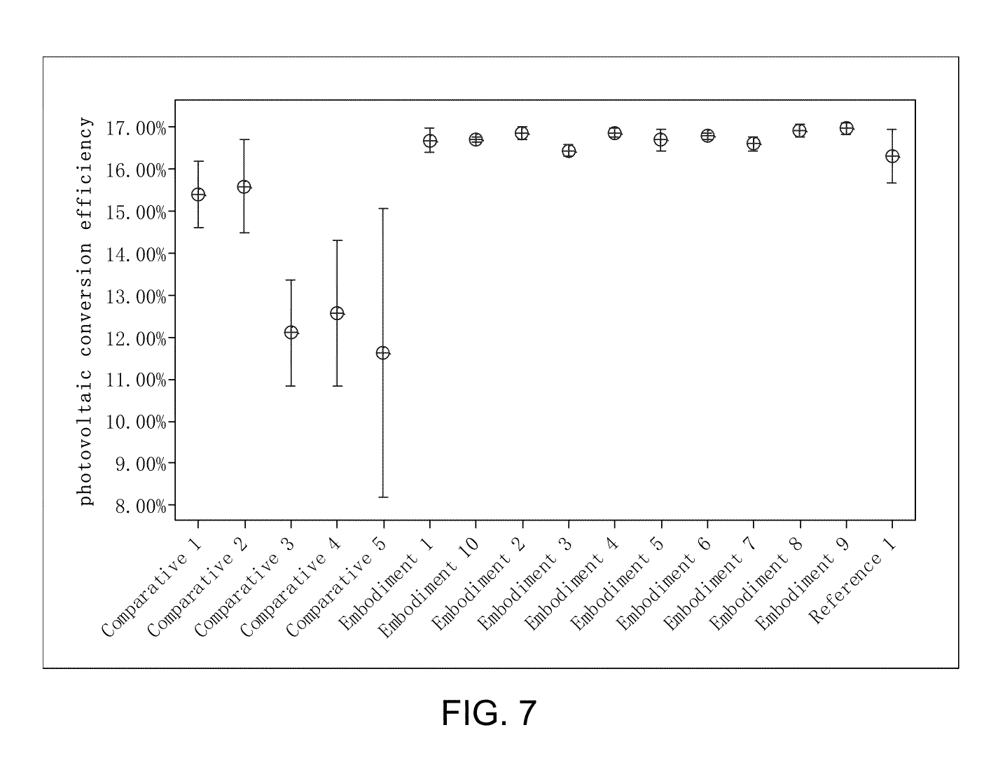

After sintering, the crystalline silicon solar cell wafers were evaluated in a ABET I-V tester. The open-circuit voltage, short-circuit current, series resistance, filling factor, and photovoltaic conversion efficiency were measured as shown in FIGS. 3 through 7 as Embodiments 1-10 and Reference 1. The results indicate that comparing to the Reference 1 the Embodiments 1-10 have higher photovoltaic conversion efficiency, higher open circuit voltage, higher short-circuit current, lower series resistance, and higher filling factor.

Comparatives 1-5

The conductive pastes used for Comparatives 1-5 are prepared as same way as the Embodiments 1-10 except the different compositions of the silver powders, glass frits, and organic media. The conductive pastes are then printed and sintered on light receiving surfaces of crystalline silicon solar cells as the same way of the Embodiments 1-10. After sintering, the crystalline silicon solar cell wafers are evaluated in a ABET I-V tester. The open-circuit voltage, short-circuit current, series resistance, filling factor, and photovoltaic conversion efficiency were measured as shown in FIGS. 3 through 7 as Comparatives 1-5. The results indicate that comparing to the Embodiments 1-10, the Comparatives 1-5 have lower photovoltaic conversion efficiency, lower open circuit voltage, lower short circuit current, higher series resistance, and lower filling factor.

Finally, the above-discussion of the embodiments, comparatives, and reference are intended to be mere illustrations of the present invention and should not be construed as limiting the appended claims to any particular embodiment or group of embodiments. Thus, while the invention has been described with reference to exemplary embodiments, it should also be appreciated that numerous modifications and alternative embodiments may be devised by those having ordinary skill in the art without departing from the broader and intended spirit and scope of the disclosure as set forth in the claims that follow. In addition, the section headings included herein are intended to facilitate a review but are not intended to limit the scope of the present system. Accordingly, the specification and drawings are to be regarded in an illustrative manner and are not intended to limit the scope of the appended claims.

What is claimed is:

1. A conductive paste for forming an electrode on a light receiving surface of a silicon solar cell, the conductive paste comprising:
a conductive powder of 70-90 wt %, the conductive powder comprising a plurality of silver particles having sizes ranging from 0.1 μm to 10 μm;
a glass frit of 0.5-10 wt %, wherein the glass frit comprises a glass network former of 5-35 wt %, a glass network intermediate of 5-30 wt %, a heavy metal fluxing agent of 50-89 wt %, and a functional agent of 1-3 wt %; and
an organic vehicle of 5-25 wt %,
wherein the glass frit is softened in a sintering process to cause a formation of a sintered silver bulk from the conductive powder, a formation of silver crystal grains, and precipitation of silver colloids at the light receiving surface, resulting in a conductive path of the electrode that reduces series resistance of the silicon solar cell.

2. The conductive paste of claim 1 wherein the glass frit comprises of 2-7 wt %.

3. The conductive paste of claim 1 wherein the glass frit comprises of 3-6 wt %.

4. The conductive paste of claim 1 wherein the glass network intermediate is 8-25 wt % in the glass frit.

5. The conductive paste of claim 1 wherein the glass network intermediate is 10-20 wt % in the glass frit.

6. The conductive paste of claim 1 wherein the glass network intermediate comprises a first material selected from zinc oxide, cadmium oxide, magnesium oxide, beryllium oxide, In₂O₃ and gallium oxide, a second material selected from Al₂O₃ and scandium oxide, and a third material selected from titanium oxide, zirconium oxide, hafnium oxide, yttrium oxide and thorium oxide, wherein the composition ratio of the first, second, and third material is selected for assisting the formation of the sintered silver bulk from the conductive powder.

7. The conductive paste of claim 1 wherein the glass network former comprises one material selected from silicon oxide, phosphorus oxide, and germanium oxide or a mixture of the above.

8. The conductive paste of claim 1 wherein the functional agent comprises one or more alkali metal elements, alkaline-earth metal elements, and main subgroup elements or their mixture.

9. The conductive paste of claim 1 wherein the heavy metal fluxing agent is selected from lead oxide and bismuth oxide.

10. The conductive paste of claim 1 wherein the silver crystal grains formed at the light receiving surface have a substantially uniform average size, the average size ranging from 20 nm to about 150 nm.

11. The conductive paste of claim 10 wherein the silver crystal grains with substantially uniform sizes further contribute to consistently high short-circuit current, consistently high open-circuit voltage, and consistently high filling factor of the silicon solar cell.

12. A glass frit comprises:
5-35 wt % of a glass network former selected from silicon oxide, germanium oxide, and phosphorus oxide;
5-30 wt % of a glass network intermediate;
50-89 wt % of a heavy metal fluxing agent selected from lead oxide and bismuth oxide; and
1-3% wt % of a functional agent made by one or more materials selected from a group consisting of alkali metals, alkaline-earth metals, and main subgroup elements.

13. The glass frit of claim 12 wherein the glass network intermediate is 8-25 wt % in the glass frit.

14. The glass frit of claim 12 wherein the glass network intermediate is 10-20 wt % in the glass frit.

15. The glass frit of claim 12 wherein the glass network intermediate comprises a first component, a second component, and a third component, wherein the first component is selected from the group consisting of zinc oxide, cadmium oxide, magnesium oxide, beryllium oxide, In₂O₃ and gallium oxide; the second component is selected from the group consisting of Al₂O₃ and scandium oxide; and the third component is selected from the group consisting of titanium oxide, zirconium oxide, hafnium oxide, yttrium oxide or thorium oxide, wherein a composition ratio of the first component, the second component, and the third component is selected for assisting a sintering process to transform a conductive paste to an electrode on an emitter surface of a silicon solar cell substantially free from any oversized and undersized silver crystal grains at the emitter surface.

16. The glass frit of claim 15 wherein the silver crystal grains at the emitter surface comprises sizes substantially uniform averaging in a range of 20 nm to about 150 nm, resulting in an electrode of the silicon solar cell that contributes to consistently high short-circuit current, consistently high open-circuit voltage, and consistently high filling factor of the silicon solar cell.

17. The glass frit of claim 15 wherein the composition ratio comprises a range of 50-85 wt % of the first component, 10-30 wt % of the second component, and 1-25 wt % of the third component.

18. The glass frit of claim 15 wherein the composition ratio comprises a range of 60-80 wt % of the first component, 15-25 wt % of the second component, and 8-18 wt % of the third component.

19. The glass frit of claim 12 is further characterized by a glass softening temperature ranging from 450° C. to 620° C.
